(19) United States
(12) Patent Application Publication
(10) Pub. No.: US 2019/0258581 A1
(43) Pub. Date: Aug. 22, 2019

(54) MEMORY SYSTEM AND OPERATING METHOD THEREOF

(71) Applicant: SK hynix Inc., Gyeonggi-do (KR)

(72) Inventor: Hui Won LEE, Seoul (KR)

(21) Appl. No.: 16/122,287

(22) Filed: Sep. 5, 2018

(30) Foreign Application Priority Data
Feb. 19, 2018 (KR) 10-2018-0019449

(51) Int. Cl. G06F 12/0893; G06F 3/06

(52) U.S. Cl. CPC G06F 12/0893; G06F 3/0622; G11C 16/0483; G06F 3/068; G06F 3/064; G06F 3/0659

(57) ABSTRACT

There are provided a memory system and an operating method thereof. The memory system includes: a memory device including a replay protected memory block (RPMB) and a normal memory block; and a memory controller for controlling overall operations of the memory device, wherein the memory controller controls the memory device to read, from the RPMB, a first RPMB data group including first data stored in the RPMB in response to a read request for the first data, which is received from a host, temporarily store the first RPMB data group, and output the first data in the first RPMB data group to the host.

### CROSS-REFERENCE TO RELATED APPLICATION

The present application claims priority under 35 U.S.C. § 119(a) to Korean patent application number 10-2018-0019449, filed on Feb. 19, 2018, which is incorporated herein by reference in its entirety.

### BACKGROUND

### Field of Invention

The present disclosure generally relates to a memory system and an operating method thereof, and more particularly, to a memory system for performing a read operation of a Replay Protected Memory Block (RPMB) and an operating method of the memory system.

### Description of Related Art

The paradigm on recent computer environment has shifted to a ubiquitous computing environment in which computing systems can be used anywhere and anytime. This promotes increasing usage of portable electronic devices such as mobile phones, digital cameras, notebook computers, and the like. Such portable electronic devices may generally include a memory system using a memory device, i.e., a data storage device. The data storage device is used as a main memory device or an auxiliary memory device of the portable electronic devices.

A storage device may include a memory device for storing data and a memory controller for controlling the memory device. The memory device is generally classified into a volatile memory device and a nonvolatile memory device.

The volatile memory loses stored data when a power supply is cut off. Examples of the volatile memory are a Static Random Access Memory (SRAM), a Dynamic RAM (DRAM), a Synchronous DRAM (SDRAM), and the like.

The nonvolatile memory retains stored data even when a power supply is cut off. Examples of the nonvolatile memory are a Read Only Memory (ROM), a Programmable ROM (PROM), an Electrically Programmable ROM (EPROM), an Electrically Erasable and Programmable ROM (EEPROM), a flash memory, a Phase-change RAM (PRAM), a Magnetic RAM (MRAM), a Resistive RAM (RRAM), a Ferroelectric RAM (FRAM), and the like.

A data storage device using a memory device has excellent stability and durability, high information access speed, and low power consumption, since there is no mechanical driving part. Examples of data storage devices of memory systems having such advantages include a Universal Serial Bus (USB) memory device, memory cards having various interfaces, a Solid State Drive (SSD), and the like.

### SUMMARY

Embodiments provide a method system having an improved operation speed and an operating method of the memory system.

According to an aspect of the present disclosure, there is provided a memory system including: a memory device including a replay protected memory block (RPMB) and a normal memory block; and a memory controller configured to control overall operations of the memory device, wherein the memory controller controls the memory device to read, from the RPMB, a first RPMB data group including first data stored in the RPMB in response to a read request for the first data, which is received from a host, temporarily store the first RPMB data group, and output the first data in the first RPMB data group to the host.

According to another aspect of the present disclosure, there is provided a memory system including: a memory device including a replay protected memory block (RPMB); and a memory controller configured to control overall operations of the memory device, wherein the memory controller controls the memory device to read, from the RPMB, a first RPMB data group including first data stored in the RPMB in response to a read request for the first data, which is received from a host, output the first data in the read first RPMB data group to the host, and temporarily stores the other data in the first RPMB data group.

According to still another aspect of the present disclosure, there is provided a method for operating a memory system, the method including: receiving from a host a first read request for first data stored in a replay protected memory block (RPMB) from a host; checking whether the first read request has been authenticated through an authentication operation; when it is determined that the first read request has been authenticated, reading a first RPMB data group including the first data, and temporarily storing the read first RPMB data group by performing a read operation on the RPMB; and outputting the first RPMB data in the read first data group to the host, and maintaining the other data except the first data in the first RPMB data group as temporarily stored.

According to another aspect of the present disclosure, there is provided a memory system including: a memory device including a replay protection memory block (RPMB) suitable for storing a plurality of RPMB data; a RPMB buffer suitable for buffering a group of RPMB data including one or more RPMB data read among the plurality of RPMB data in the RPMB; a controller suitable for: authenticating an access request for target RPMB data; and providing, in response to the access request, the target RPMB data from the RPMB buffer when the target RPMB data is buffered in the RPMB buffer, and from the RPMB through the RPMB buffer when the target RPMB data is not buffered in the RPMB buffer.

### BRIEF DESCRIPTION OF THE DRAWINGS

Various embodiments will now be described more fully with reference to the accompanying drawings; however, elements and features of the present disclosure may be configured or arranged differently than shown or described herein. Thus, the present invention is not limited to the embodiments set forth herein. Rather, these embodiments are provided so that this disclosure is thorough and complete and fully conveys the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system according to an embodiment of the present disclosure.

FIG. 2 is a diagram illustrating exemplary configurations of a memory controller and a memory device of FIG. 1.

FIG. 3 is a diagram illustrating an exemplary configuration of a replay protected memory block engine of FIG. 2.

FIG. 4 is a diagram illustrating an exemplary configuration of a replay protected memory block of FIG. 2.

FIG. 5 is a diagram illustrating another embodiment of the memory controller of FIG. 1.

FIG. 6 is a diagram illustrating an exemplary configuration of the memory device of FIG. 1.

FIG. 7 is a diagram illustrating an exemplary configuration of a memory block of FIG. 6.

FIG. 8 is a diagram illustrating an embodiment of a three-dimensionally configured memory block.

FIG. 9 is a diagram illustrating another embodiment of the three-dimensionally configured memory block.

FIG. 10 is an operating method of the memory system according to an embodiment of the present disclosure.

FIG. 11 is a diagram illustrating another embodiment of the memory system.

FIG. 12 is a diagram illustrating another embodiment of the memory system.

FIG. 13 is a diagram illustrating another embodiment of the memory system.

FIG. 14 is a diagram illustrating another embodiment of the memory system.

### DETAILED DESCRIPTION

The specific structural and functional description herein is for the purpose of describing embodiments of the present disclosure. The embodiments of the present disclosure can be implemented in various forms, and thus, the present invention is not limited to the embodiments set forth herein.

The embodiments of the present disclosure can be modified in various ways; elements and features are represented in the drawings by way of example. Thus, the embodiments are not construed as limited to specifics disclosed; rather, the embodiments include all changes, equivalents, or substitutes that do not depart from the spirit and technical scope of the present disclosure. Throughout the specification, reference to “an embodiment” or the like is not necessarily to only one embodiment, and different references to “an embodiment” or the like are not necessarily to the same embodiment(s).

While terms such as “first” and “second” may be used to identify various components, such components are not limited by these identifiers. The above terms are used only to distinguish one component from another that otherwise have the same or similar names. For example, a first component may be referred to as a second component without departing from the scope of rights of the present disclosure, and likewise a second component may be referred to as a first component.

It will be understood that when an element is referred to as being “connected” or “coupled” to another element, it can be directly connected or coupled to the other element or one or more intervening elements may also be present. In contrast, when an element is referred to as being “directly connected” or “directly coupled” to another element, no intervening elements are present. Other expressions describing relationships between components such as “˜between,” “immediately ˜between” or “adjacent to˜” and “directly adjacent to˜” may be construed similarly.

The terms used in the present application are merely used to describe particular embodiments and are not intended to limit the present disclosure. Singular forms in the present disclosure are intended to include the plural forms and vice versa, unless the context clearly indicates otherwise. It will be further understood that terms such as “including” or “having,” etc., are intended to indicate the existence of stated features, numbers, operations, actions, components, parts, or combinations but are not intended to preclude the inclusion or addition of one or more other features, numbers, operations, actions, components, parts, or combinations thereof.

So far as not being differently defined, all terms used herein including technical or scientific terminologies have meanings that they are commonly understood by those skilled in the art to which the present disclosure pertains. The terms having the definitions as defined in the dictionary should be understood such that they have meanings consistent with the context of the related technique. So far as not being clearly defined in this application, terms should not be understood in an ideally or excessively formal way.

In describing embodiments, description of techniques that are well known to the art to which the present disclosure pertains and not directly related to the present disclosure may be omitted. This serves to more clearly present elements and features of the present invention.

Various embodiments of the present disclosure will be described in detail with reference to the accompanying drawings in order for those skilled in the art to be able to readily implement the present disclosure.

FIG. 1 is a diagram illustrating a memory system according to an embodiment of the present disclosure.

Referring to FIG. 1, the memory system 1000 may include a memory device 1100 for storing data and a memory controller 1200 for controlling the memory device 1100 under the control of a host 2000.

The host 2000 may communicate with the memory system 1000 by using an interface protocol such as Peripheral Component Interconnect-Express (PCI-E Advanced Technology Attachment (ATA), Serial ATA (SATA), Parallel ATA (DATA), or Serial Attached SCSI (SAS). Interface protocols between the host 2000 and the memory system 1000 are not limited to the above-described examples; other interface protocols such as a Universal Serial Bus (USB), a Multi-Media Card (MMC), an Enhanced Small Disk Interface (ESDI), and Integrated Drive Electronics (IDE) may be used instead.

The memory device 1100 may include a memory cell array (not shown) including a plurality of memory cells for storing data. In an embodiment, the memory device 1100 may be a Double Data Rate Synchronous Dynamic Random Access Memory (DDR SDRAM), a Low Power Double Data Rate 4 (LPDDR4) SDRAM, a Graphics Double Data Rate (DDDR) SRAM, a Low Power DDR (LPDDR), a Rambus Dynamic Random Access Memory (RDRAM), a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or the like.

The memory device 1100 is configured to receive a command and an address from the memory controller 1200 and access an area selected by the address in the memory cell array. That is, the memory device 1100 may perform an operation corresponding to the command on the area selected by the address. For example, the memory device 1100 may perform a program operation, a read operation, and an erase operation. In the program operation, the memory device 1100 may program data in the area selected by the address. In the read operation, the memory device 1100 may read data from the area selected by the address. In the erase operation, the memory device 1100 may erase data stored in the area selected by the address.

In an embodiment, the program operation and the read operation may be performed in units of pages, and the erase operation may be performed in units of blocks.

The memory controller 1200 may control overall operations of the memory device 1100. The memory controller 1200 may control an operation of the memory device 1100 in response to a request from the host 2000 or in the absence of a request from the host 2000.

For example, the memory controller 1200 may control the memory device 1100 to perform a program operation, a read operation, an erase operation, or the like in response to a request from the host 2000. In the program operation, the memory controller 1200 may provide a program command, an address, and data to the memory device 1100. In the read operation, the memory controller 1200 may provide a read command and an address to the memory device 1100. In the erase operation, the memory controller 1200 may provide an erase command and an address to the memory device 1100.

In an embodiment, the memory controller 1200 may autonomously generate a program command, an address, and data without any request from the host 2000, and transmit the program command, the address, and the data to the memory device 1100. For example, the memory controller 1200 may provide the command, the address, and the data to the memory device 1100 to perform background operations such as a program operation for wear leveling and a program operation for garbage collection.

The memory controller 1200 may execute firmware (FW) for controlling the memory device 1100. When the memory device 1100 is a flash memory device, the memory controller 1200 may be configured to operate firmware such as a Flash Translation Layer (FTL) for controlling communication between the host 2000 and the memory device 1100. Specifically, the memory controller 1200 may translate a logical address included in a request from the host 2000 into a physical address that is an address to be provided to the memory device 1100.

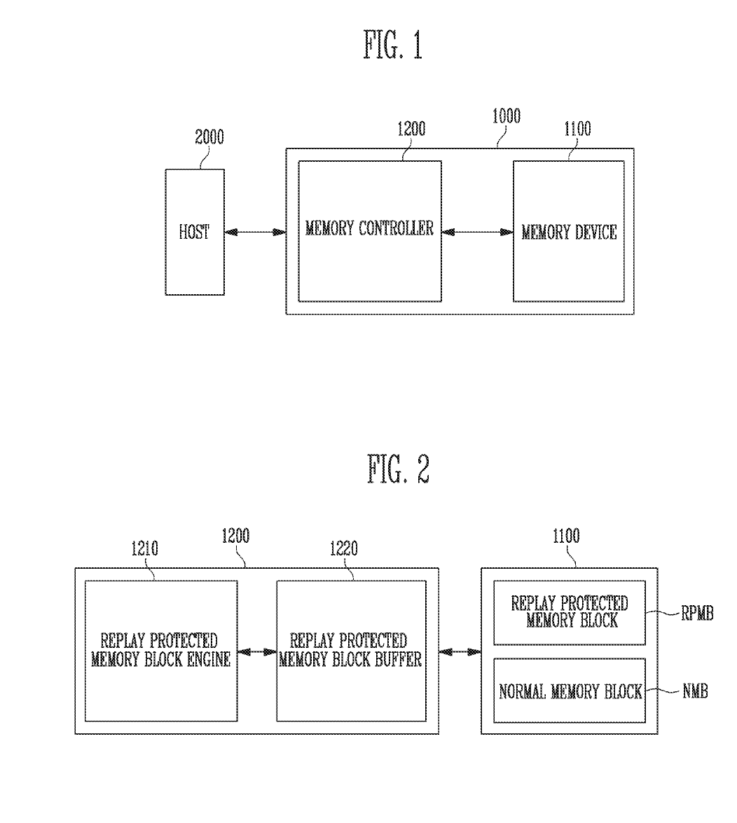

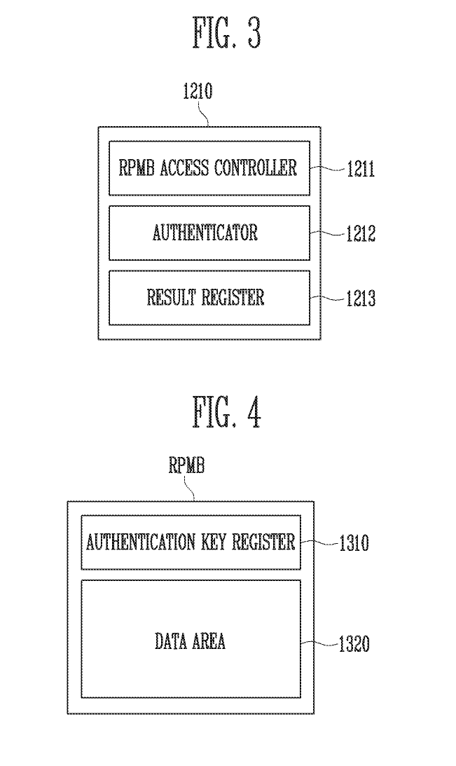

FIG. 2 is a diagram illustrating the memory controller 1200 and the memory device 1100 of FIG. 1.

Referring to FIG. 2, the memory device 1100 may include a replay protected memory block (hereinafter, referred to as RPMB) and a normal memory block (hereinafter, referred to as NMB)

The RPMB may be a partial area in the memory cell array included in the memory device 1100. For example, the memory system 1000 (of FIG. 1) may store data in a plurality of partitions into which the area of the memory device 1100 is divided. In an embodiment, the plurality of partitions may be a booting area, a user data area, and an RPMB area.

The RPMB area may include at least one RPMB. The RPMB may be an area that allows only a limited access. The RPMB may store data in a manner to protect the data from replay attacks. Data stored in the RPMB may require high security, such as main information or secret information of a user.

A replay attack may mean that valid data transmission between the host 2000 (of FIG. 1) and the memory device 1100 is intercepted, recorded, and played back again later by an attacker.

The NMB may be the other area except the RPMB in the memory cell array included in the memory device 1100. Also, the NMB may be included in the other areas except the RPMB area, e.g., the booting area and the user data area in the memory device 1100. A program operation, a read operation, and an erase operation of normal data and system data may be performed in the NMB under the control of the memory controller 1200.

The memory controller 1200 may include a RPMB engine 1210 for performing an operation of accessing the RPMB and a RPMB buffer 1220 for storing data read from the RPMB.

The RPMB engine 1210 may control read and write operations on the RPMB, using an authentication key stored in the RPMB. In an embodiment, the authentication key may be included in a Message Authentication Code (MAC) and may be used for the authentication for the read and write operations on the RPMB. The authentication key may be pre-programmed and stored in the RPMB.

In an embodiment, the RPMB engine 1210 may use a hash algorithm for security. The RPMB engine 1210 may generate a MAC based on the request from the host 2000 and the authentication key, compare the generated MAC with a MAC provided from the host 2000. When the generated MAC and the provided MAC are identical to each other, the RPMB engine 1210 may determine that a read or write request for the RPMB has been authenticated.

When a read request for the RPMB, which is received from the host 2000, is authenticated by the RPMB engine 1210, the RPMB buffer 1220 temporarily stores a plurality of RPMB data read from the RPMB. For example, when the host 2000 transmits a read request for first RPMB data among the plurality of RPMB data stored in the RPMB, the memory device 1100 reads a RPMB data group including the first RPMB data from the RPMB, and the RPMB buffer 1220 temporarily stores the read RPMB data group.

Then, the RPMB buffer 1220 outputs the first RPMB data in the temporarily stored RPMB data group to the host 2000, and maintains the other data, except the first RPMB data in the RPMB data group, buffered in the RPMB buffer 1220.

Then, when the host 2000 transmits a read request for second RPMB data among the plurality of RPMB data stored in the RPMB, the RPMB buffer 1220 checks whether the second RPMB data exists by searching for it in the temporarily stored data.

When the second RPMB data is found in the RPMB buffer 1220, the RPMB buffer 1220 may output the second RPMB data to the host 2000. The memory device 1100 may skip a read operation on the second RPMB data stored in the RPMB.

As an example, the size of the RPMB data requested from the host 2000 may be a first data size (e.g., 128 bytes), and the size of RPMB data, which the memory device 1100 reads and outputs to the RPMB buffer 1220, may be a second data size larger than the first data size. For example, the second data size may correspond to one page of a memory block, or to the maximum capacity of the RPMB buffer 1220.

The RPMB buffer 1220 may be configured to include a RPMB buffer controller for controlling input and output operations of RPMB data. In addition, the RPMB buffer controller may search for specific RPMB data in the RPMB buffer 1220.

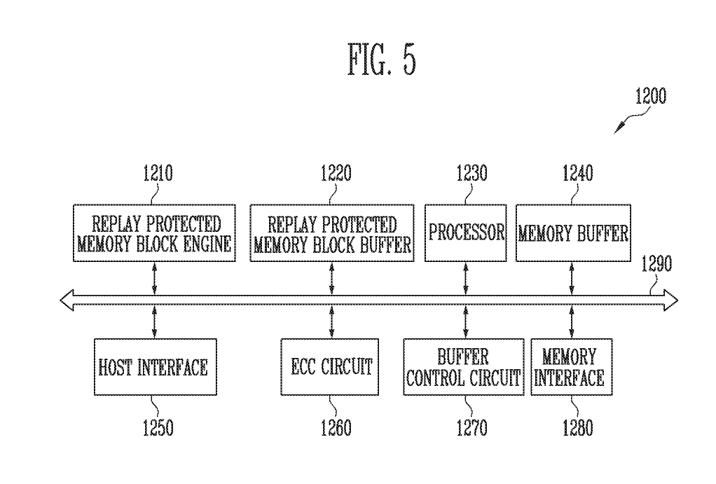

FIG. 3 is a diagram illustrating the RPMB engine 1210 of FIG. 2.

The RPMB engine 1210 may include an RPMB access controller 1211, an authenticator 1212, and a result register 1213.

The RPMB access controller 1211 may receive a write request or read request for the RPMB from the host 2000 (of FIG. 1), and store a result obtained by processing such request in the result register 1213. The RPMB access controller 1211 may output a value stored in the result register 1213 as a response to the request from the host 2000.

The authenticator 1212 may authenticate the read request or write request for the RPMB from the host 2000 through the request and the MAC provided from the host 2000 and the authentication key stored in the RPMB. In an embodiment, the authenticator 1212 may authenticate the request of the host 2000 according to the hash algorithm. For example, the authentication process may be performed according to the hash-based security scheme such as the hash-based message authentication code secure hash algorithm 256 (HMAC SHA-256).

The result register 1213 may store a result of an access request for the RPMB from the host 2000.

FIG. 4 is a diagram illustrating the RPMB of FIG. 2.

The RPMB may include an authentication key register 1310 and a data area 1320.

The authentication key register 1310 may store an authentication key. In an embodiment, the authentication key register 1310 may be a One Time Programmable (OTP) register. The authentication key register 1310 is not overwritten or erased. The authentication key may be used when the authenticator 1212 (of FIG. 3) of the RPMB engine 1210 (of FIG. 3) authenticates the access from the host 2000 (of FIG. 1) for the RPMB data stored in the data area 1320.

The data area 1320 may be read or written through only an authenticated access. The data area 1320 may store RPMB data. In a read operation, the data area 1320 may be read together with a RPMB data group having a data size equal to the read data size (page unit) of the normal memory block NMB (of FIG. 2) or a data size equal to the maximum capacity of the RPMB buffer 1220 (of FIG. 2).

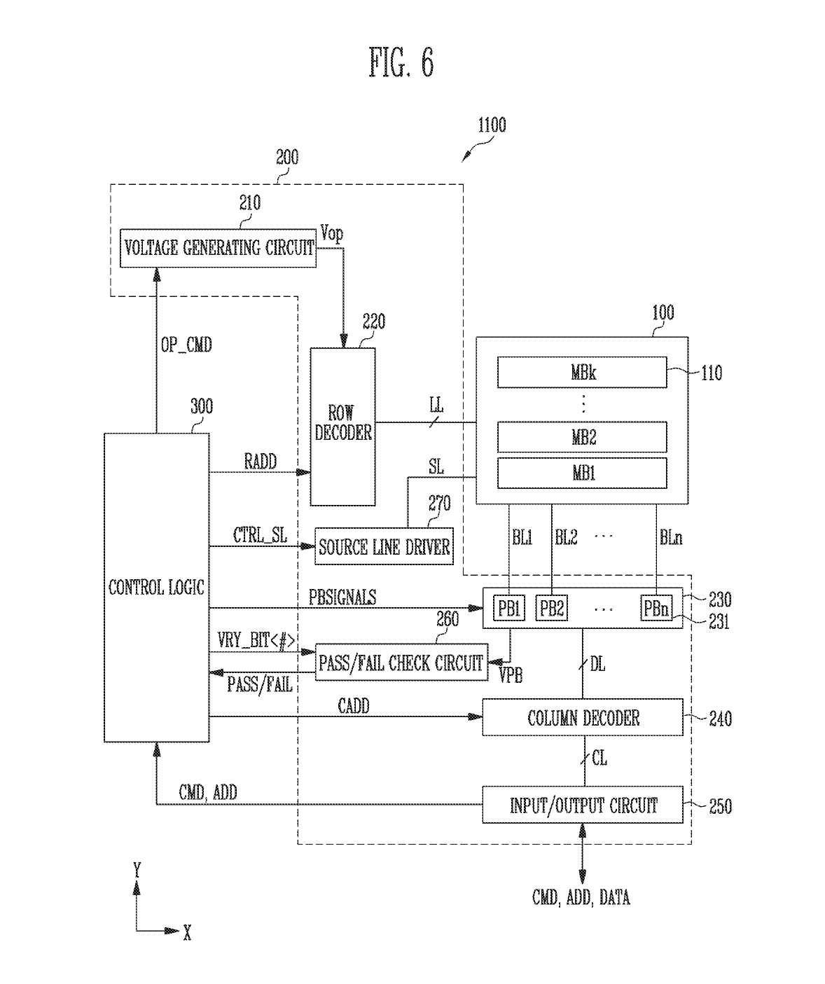

FIG. 5 is a diagram illustrating another embodiment of the memory controller of FIG. 1.

Referring to FIG. 5, the memory controller 1200 may include the RPMB engine 1210, the RPMB buffer 1220, a processor 1230, a memory buffer 1240, a host interface 1250, an ECC circuit 1260, a buffer control circuit 1270, a memory interface 1280, and a bus 1290.

The RPMB engine 1210 and the RPMB buffer 1220 of FIG. 5 may be configured and operated identically to their respective counterparts of FIG. 3, which are described above.

The processor 1230 may control overall operations of the memory controller 1200 and perform a logical operation. The processor 1230 may communicate with the external host 2000 (of FIG. 1) through the host interface 1250, and communicate with the memory buffer 1240 through the buffer control circuit 1270. The processor 1230 may control an operation of the memory system, using the memory buffer 1240 as a working memory, a cache memory or a buffer memory.

The processor 1230 may perform a function of a flash translation layer (FTL). The processor 1230 may translate a logical block address (LBA) provided by the host through the FTL into a physical block address (PBA). The FTL may receive an LBA, using a mapping table, to be translated into a PBA. Several address mapping methods of the FTL exist according to mapping units. A representative address mapping method includes a page mapping method, a block mapping method, and a hybrid mapping method.

The processor 1230 is configured to randomize data received from the host 2000. For example, the processor 1230 may randomize data received from the host 2000, using a randomizing seed. The randomized data is provided as data to be stored to the memory device 1100 to be programmed in the memory cell array.

In a read operation, the processor 1230 is configured to derandomize data received from the memory device 1100. For example, the processor 1230 may derandomize data received from the memory device 1100, using a derandomizing seed. The derandomized data may be output to the host 2000.

In an embodiment, the processor 1230 may perform randomizing and derandomizing by driving software or firmware.

In an embodiment, the processor 1230 may include the RPMB engine 1210.

The memory buffer 1240 may be used as the working memory, the cache memory, or the buffer memory of the processor 1230. The memory buffer 1240 may store codes and commands, which are executed by the processor 1230. The memory buffer 1240 may include a Static RAM (SRAM) or a Dynamic RAM (DRAM).

In an embodiment, the memory buffer 1240 may include the RPMB buffer 1220.

The host interface 1250 may communicate with the external host 2000 under the control of the processor 1230. The host interface 1250 may communicate with the host using at least one of various communication protocols, such as a Universal Serial bus (USB), a Serial AT Attachment (SATA), a High Speed InterChip (HSIC), a Small Computer System Interface (SCSI), Firewire, a Peripheral Component Interconnection (PCI), a PCI express (PCIe), a nonvolatile memory express (NVMe), a universal flash storage (UFS), a Secure Digital (SD), a Multi-Media Card (MMC), an embedded MMC (eMMC), a Dual In-line Memory Module (DIMM), a Registered DIMM (RDIMM), and a Load Reduced DIMM (LRDIMM).

The ECC circuit 1260 may perform an ECC operation. The ECC circuit 1260 may perform ECC encoding on data to be written in the memory device 1100 through the memory interface 1280. The ECC encoded data may be transferred to the memory device 1100 through the memory interface 1280. The ECC circuit 1260 may perform ECC decoding on data received from the memory device 1100 through the memory interface 1280.

The buffer control circuit 1270 may control the memory buffer 1240 under the control of the processor 1230.

The memory interface 1280 may communicate with the memory device 1100 under the control of the processor 1230. The memory interface 1280 may communicate a command, an address, and data with the memory device 1100 through a channel.

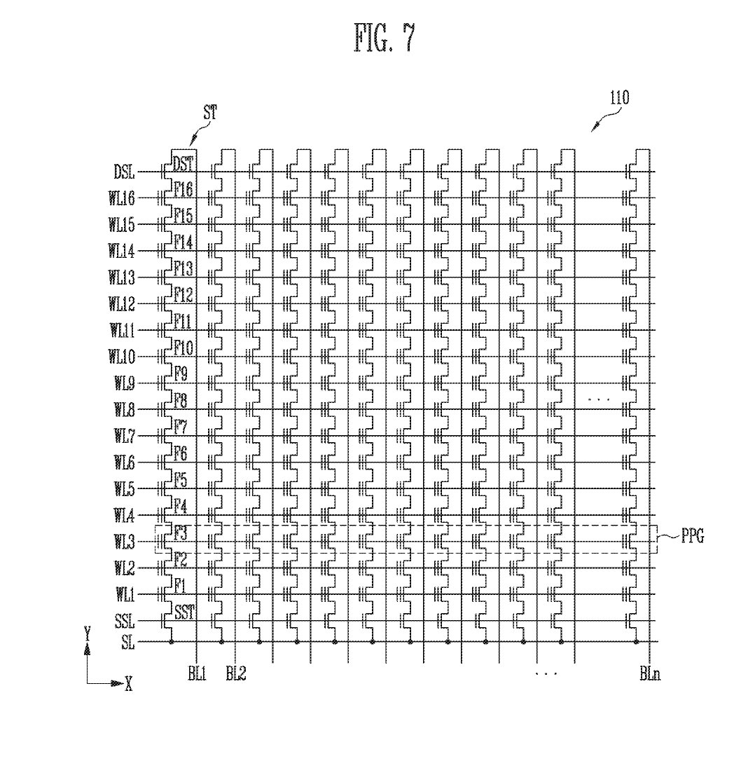

FIG. 6 is a diagram illustrating the memory device of FIG. 1.

Referring to FIG. 6, the memory device 1110 may include a memory cell array 100 that stores data. The memory device 1110 may include peripheral circuits 200 configured to perform a program operation for storing data in the memory cell array 100, a read operation for outputting the stored data, and an erase operation for erasing the stored data. The memory device 1110 may include a control logic 300 that controls the peripheral circuits 200 under the control of the memory controller 1200 (of FIG. 1).

The memory cell array 100 may include a plurality of memory blocks MB1 to MBk (k is a positive integer) 110. Local lines LL and bit lines BL1 to BLn (n is a positive integer) may be coupled to the memory blocks MB1 to MBk 110. For example, the local lines LL may include a first select line, a second select line, and a plurality of word lines arranged between the first and second select lines. Also, the local lines LL may further include dummy lines arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be coupled to the memory blocks MB1 to MBk 110, respectively, and the bit lines BL1 to BLn may be commonly coupled to the memory blocks MB1 to MBk 110. The memory blocks MB1 to MBk 110 may be implemented in a two-dimensional or three-dimensional structure. For example, memory cells may be arranged in a direction parallel to a substrate in memory blocks 110 having a two-dimensional structure. For example, memory cells may be arranged in a direction vertical to a substrate in memory blocks 110 having a three-dimensional structure.

The peripheral circuits 200 may be configured to perform program, read, and erase operations of a selected memory block 110 under the control of the control logic 300. For example, the peripheral circuits 200, under the control of the control logic 300, may supply verify and pass voltages to the first select line, the second select line, and the word lines, selectively discharge the first select line, the second select line, and the word lines, and verify memory cells coupled a selected word line among the word lines. For example, the peripheral circuits 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop used for program, read, and erase operations in response to an operation signal OP_CMD. Also, the voltage generating circuit 210 may selectively discharge the local lines LL in response to the operation signal OP_CMD. For example, the voltage generating circuit 210 may generate a program voltage, a verify voltage, pass voltages, a read voltage, a source line voltage, and the like under the control of the control logic 300.

The row decoder 220 may transfer the operating voltages Vop to local lines LL coupled to a selected memory block 110 in response to a row address RADD.

The page buffer group 230 may include a plurality of page buffers PB1 to PBn 231 coupled to the bit lines BL1 to BLn. The page buffers PB1 to PBn 231 may operate in response to page buffer control signals PBSIGNALS. For example, the page buffers PB1 to PBn 231 may temporarily store data received through the bit lines BL1 to BLn, or sense voltages or current of the bit lines BL1 to BLn in a read or verify operation.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer a command CMD and an address ADD, which are received from the memory controller (1200 of FIG. 1), to the control logic 300, or communicate data DATA with the column decoder 240.

In a read operation and a verify operation, the pass/fail check circuit 260 may generate a reference current in response to a permission bit VRY_BIT<#>, and output a pass signal PASS or a fail signal FAIL by comparing a sensing voltage VPB received from the page buffer group 230 with a reference voltage generated by the reference current.

The source line driver 270 may be coupled to a memory cell included in the memory cell array 100 through a source line SL, and control the voltage of a source node. As an example, in a read or verify operation, the source line driver 270 may electrically couple a source node of the memory cell to a ground node. Also, in a program operation, the source line driver 270 may apply a ground voltage to the source node of the memory cell. In an erase operation, the source line driver 270 may apply an erase voltage to the source node of the memory cell. The source line driver 270 may receive a source line control signal CTRL_SL from the control logic 300, and control the voltage of the source node, based on the source line control signal CTRL_SL.

The control logic 300 may control the peripheral circuits 200 by outputting the operation signal OP_CMD, the row address RADD, the page buffer control signals PBSIGNALS, and the permission bit VRY_BIT<#> in response to the command CMD and the address ADD. Also, the control logic 300 may determine whether the verify operation has passed or failed in response to the pass or fail signal PASS or FAIL.

FIG. 7 is a diagram illustrating the memory block of FIG. 6.

Referring to FIG. 7, in the memory block 110, a plurality of word lines arranged in parallel to one another may be coupled between a first select line and a second select line. The first select line may be a source select line SSL, and the second select line may be a drain select line DSL. More specifically, the memory block 110 may include a plurality of strings ST coupled between bit lines BL1 to BLn and a source line SL. The bit lines BL1 to BLn may be coupled to the strings ST, respectively, and the source line SL may be commonly coupled to the strings ST. The strings ST may be configured identically to one another, and therefore, a string ST coupled to a first bit line BL1 will be described in detail as an example.

The string ST may include a source select transistor SST, a plurality of memory cells F1 to F16, and a drain select transistor DST, which are coupled in series to each other between the source line SL and the first bit line BL1. At least one source select transistor SST and at least one drain select transistor DST may be included in one string ST, and more than the 16 memory cells F1 to F16 shown in the drawing may be included in one string ST.

A source of the source select transistor SST may be coupled to the source line SL, and a drain of the drain select transistor DST may be coupled to the first bit line BL1. The memory cells F1 to F16 may be coupled in series between the source select transistor SST and the drain select transistor DST. Gates of source select transistors SST included in different strings ST may be coupled to the source select line SSL, gates of drain select transistors DST included in different strings ST may be coupled to the drain select line DSL, gates of the memory cells F1 to F16 included in different strings ST may be coupled to a plurality of word lines WL1 to WL16. A group of memory cells coupled to the same word line among the memory cells included in different strings ST may be a physical page PPG. Therefore, physical pages PPG of which number corresponds to that of the word lines WL1 to WL16 may be included in the memory block 110.

One memory cell (each of F1 to F16) may store data of one bit. This is generally called as a single level cell (SLC). One physical page PPG may store one logical page (LPG) data. The one LPG data nr ay include data bits of which number corresponds to that of cells included in one physical page PPG. In addition, one memory cell may store data of two or more bits. This is generally called as a multi-level cell. One physical page PPG may store two or more LPG data.

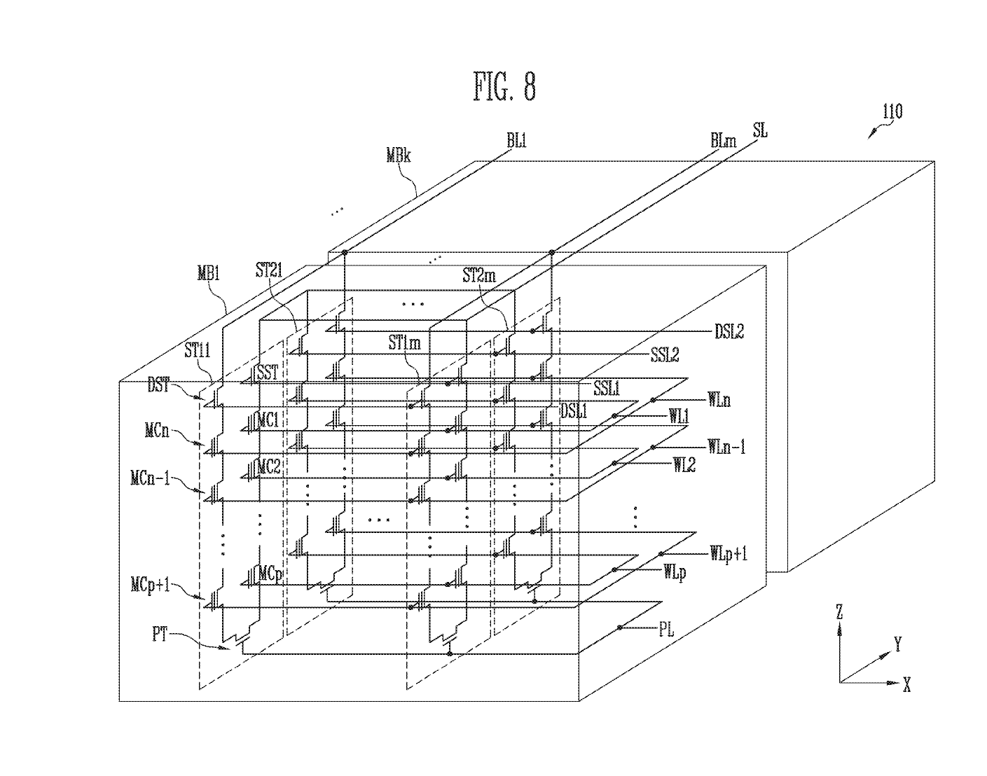

FIG. 8 is a diagram illustrating an embodiment of a three-dimensionally configured memory block.

Referring to FIG. 8, the memory cell array 100 may include a plurality of memory blocks MB1 to MBk 110. The memory block 110 may include a plurality of strings ST11 to ST1m and ST21 to ST2m. In an embodiment, each of the plurality of strings ST11 to ST1m and ST21 to ST2m may be formed in a ‘U’ shape. In the memory block 110, m strings may be arranged in a row direction (X direction). In FIG. 8, it is illustrated that two strings are arranged in a column direction (Y direction). However, this is an example only; three or more strings may be arranged in the column direction (Y direction).

Each of the plurality of strings ST11 to ST1m and ST21 to ST2m may include at least one source select transistor SST, first to nth memory cells MC1 to MCn, a pipe transistor PT, and at least one drain select transistor DST.

The source and drain select transistors SST and DST and the memory cells MC1 to MCn may have structures similar to one another. For example, each of the source and drain select transistors SST and DST and the memory cells MC1 to MCn may include a channel layer, a tunnel insulating layer, a charge trapping layer, and a blocking insulating layer. For example, a pillar for providing the channel layer may be provided in each string. For example, a pillar for providing at least one of the channel layer, the tunnel insulating layer, the charge trapping layer, and the blocking insulating layer may be provided in each string.

The source select transistor SST of each string may be coupled between a source line SL and memory cells MC1 to MCp.

In an embodiment, source select transistors of strings arranged in the same row may be coupled to a source select line extending in the row direction, and source select transistors of strings arranged in different rows may be coupled to different source select lines. In FIG. 8, source select transistors of strings ST11 to ST1m of a first row may be coupled to a first source select line SSL1. Source select transistors of strings ST21 to ST2m of a second row may be coupled to a second source select line SSL2.

In another embodiment, the source select transistors of the strings ST11 to ST1m and ST21 to ST2m may be commonly coupled to one source select line.

First to nth memory cells MC1 to MCn of each string may be coupled between the source select transistor SST and the drain select transistor DST.

The first to nth memory cells MC1 to MCn may be divided into first to pth memory cells MC1 to MCp and (p+1)th to nth memory cells MCp+1 to MCn. The first to pth memory cells MC1 to MCp may be sequentially arranged in a vertical direction (Z direction), and be coupled in series to each other between the source select transistor SST and the pipe transistor PT. The (p+1)th to nth memory cells MCp+1 to MCn may be sequentially arranged in the vertical direction (Z direction), and be coupled in series to each other between the pipe transistor PT and the drain select transistor DST. The first to pth memory cells MC1 to MCp and the (p+1)th to nth memory cells MCp+1 to MCn may be coupled to each other through the pipe transistor PT. Gates of the first to nth memory cells MC1 to MCn of each string may be coupled to first to nth word lines WL1 to WLn, respectively.

In an embodiment, at least one of the first to nth memory cells MC1 to MCn may be used as a dummy memory cell. When a dummy memory cell is provided, the voltage or current of a corresponding string can be stably controlled. A gate of the pipe transistor PT of each string may be coupled to a pipe line PL.

The drain select transistor DST of each string may be coupled to a bit line and the memory cells MCp+1 to MCn. Strings arranged in the row direction may be coupled to a drain select line extending in the row direction. Drain select transistors of the strings ST11 to ST1, of the first row may be coupled to a first drain select line DSL1. Drain select transistors of the strings ST21 to ST2m of the second row may be coupled to a second drain select line DSL2.

Strings arranged in the column direction may be coupled to bit lines extending in the column direction. In FIG. 8, strings ST11 and ST21 of a first column may be coupled to a first bit line BL1. Strings ST1m and ST2m of an mth column may be coupled to an nth bit line BLn.

Memory cells coupled to the same word line among the strings arranged in the row direction may constitute one page. For example, memory cells coupled to the first word line WL1 among the strings ST11 to ST1m of the first row may constitute one page. Memory cells coupled to the first word line WL1 among the strings ST21 to ST2m of the second row may constitute another page. As any one of the drain select lines DSL1 and DSL2 is selected, strings arranged in one row direction may be selected. As any one of the word lines WL1 to WLn is o selected, one page among the selected strings may be selected.

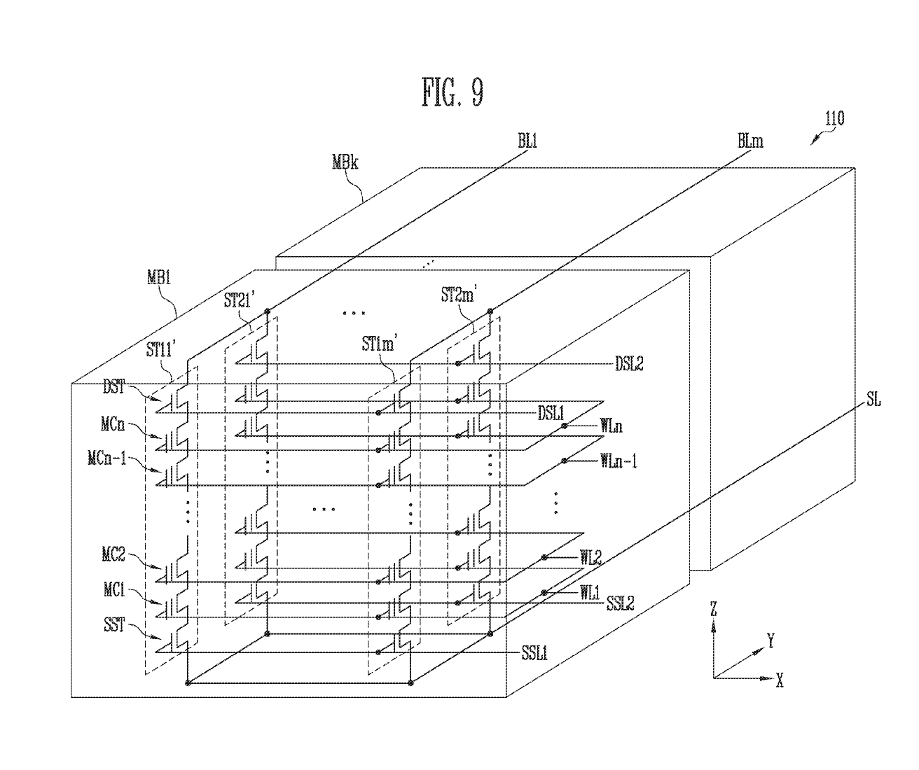

FIG. 9 is a diagram illustrating another embodiment of the three-dimensionally configured memory block.

Referring to FIG. 9, the memory cell array 100 may include a plurality of memory blocks MB1 to MBk 110. The memory block 110 may include a plurality of strings ST11′ to ST1m′ and ST21′ to ST2m′. Each of the plurality of strings ST11′ to ST1m′ and ST21′ to ST2m′ may extend along a vertical direction (Z direction). In the memory block 110, strings may be arranged in a row direction (X direction). In FIG. 9, it is illustrated that two strings are arranged in a column direction (Y direction). However, this is merely an example; three or more strings may be arranged in the column direction (Y direction).

Each of the plurality of strings ST11′ to ST1m′ and ST21′ to ST2m′ may include at least one source select transistor SST, first to nth memory cells MC1 to MCn, and at least one drain select transistor DST.

The source select transistor SST of each string may be coupled between a source line SL and the memory cells MC1 to MCn. Source select transistors of strings arranged in the same row may be coupled to the same source select line. Source select transistors of strings ST11′ to ST1m° arranged on a first row may be coupled to a first source select line SSL1. Source select transistors of strings ST21° to ST2m′ arranged on a second row may be coupled to a second source select line SSL2. In another embodiment, the source select transistors of the strings ST11′ to ST1m° and ST21° to ST2m′ may be commonly coupled to one source select line.

The first to nth memory cells MC1 to MCn of each string may be coupled in series to each other between the source select transistor SST and the drain select transistor DST. Gates of the first to nth memory cells MC1 to MCn may be coupled to first to nth word lines WL1 to WLn, respectively.

In an embodiment, at least one of the first to nth memory cells MC1 to MCn may be used as a dummy memory cell. When a dummy memory cell is provided, the voltage or current of a corresponding string can be stably controlled. Accordingly, the reliability of data stored in the memory block 110 can be improved.

The drain select transistor DST of each string may be coupled between a bit line and the memory cells MC1 to MCn. Drain select transistors DST of strings arranged in the row direction may be coupled to a drain select line extending in the row direction. The drain select transistors DST of the strings ST11′ to ST1m′ of the first row may be coupled to a first drain select line DSL1. The drain select transistors DST of the strings ST21′ to ST2m′ of the second row may be coupled to a second drain select line DSL2.

That is, the memory block 110 of FIG. 9 may have a circuit similar or equivalent to that of the memory block 110 of FIG. 8, except that the pipe transistor PT is excluded from each string.

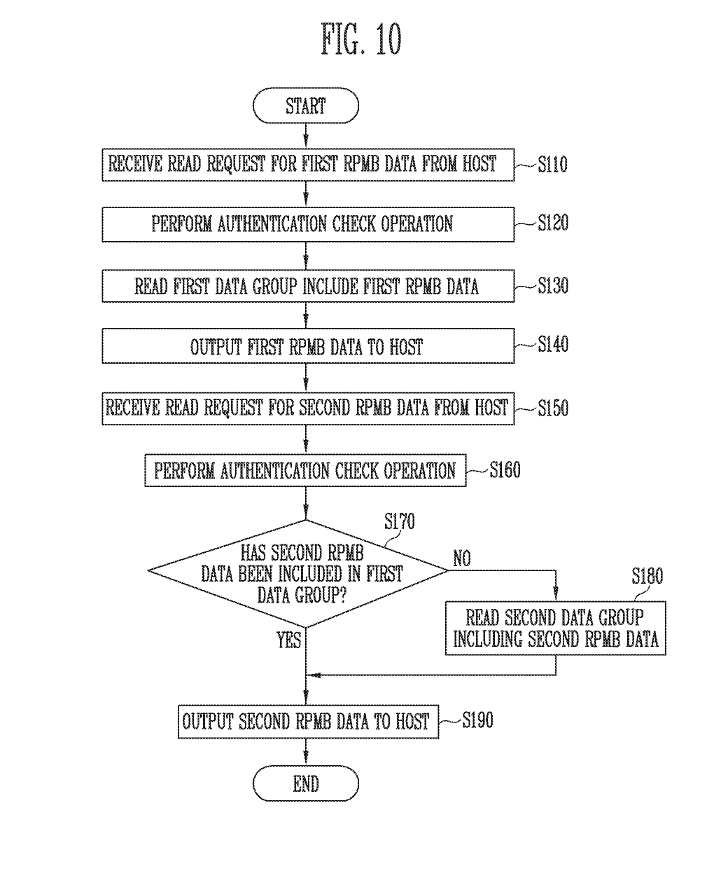

FIG. 10 is an operating method of the memory system 1000 according to an embodiment of the present disclosure.

The operating method of the memory system 1000 according to an embodiment of the present disclosure will be described as follows with reference to FIGS. 1 to 10.

In an embodiment of the present disclosure, a case where the host 2000 transmits a read request for some RPMB data (first RPMB data and second RPMB data) among a plurality of RPMB data stored in the RPMB will be described as an example.

When a read request for the first RPMB data among the plurality of RPMB data stored in the RPMB is received from the host 2000 at step S110, the RPMB engine 1210 of the memory controller 1200 generates or calculates an MAC, using an authentication key stored in the RPMB, and performs an authentication check operation by determining whether the calculated MAC is equal to an MAC included in the read request from the host 2000 at step S120. If the generated MAC is equal to the MAC included in the read request from the host 2000, the RPMB engine 1210 may determine that the read request for the RPMB has been authenticated. If the generated MAC is different from the MAC included in the read request from the host 2000, the RPMB engine 1210 may determine that the read request from the host 2000 has not been authenticated, and output as a response, to the host 2000, a result indicating that the authentication of the read request has failed.

When the read request from the host 2000 is authenticated by the above-described authentication check operation at step S120, the processor 1230 controls the memory device 1100 to read a first RPMB data group including the first RPMB data among the plurality of RPMB data stored in the RPMB. The data size of the first RPMB data group may have a second data size larger than the data size of the first RPMB data, i.e., larger than a first data size of, e.g., 128 bytes. For example, the second data size may correspond to a page that is a basic program or read unit of is the memory device 1100, or be the maximum capacity of the RPMB buffer 1220.

The memory device 1100 performs a read operation on the RPMB under the control of the processor 1230 at step S130, and the first RPMB data group read as a result of the read operation is stored in the RPMB buffer 1220.

The RPMB buffer 1220 outputs the first RPMB data in the stored first RPMB data group to the host 2000 at step S140, and maintains the other data, except the first RPMB data in the first RPMB data group, buffered in the RPMB buffer 1220.

After this, when a read request for the second RPMB data among the plurality of RPMB data stored in the RPMB is received from the host 2000 at step S150, the RPMB engine 1210 of the memory controller 1200 generates or calculates an MAC, using the authentication key stored in the RPMB, and performs an authentication check operation by determining whether the generated MAC is equal to an MAC included in the read request from the host 2000 at step S160. The authentication check operation at step S160 is identical to the above-described authentication check operation at step S120.

The RPMB buffer 1220 checks whether the second RPMB data exists by searching the buffered first RPMB data group for the second RPMB data at step S170.

When the second RPMB is temporarily stored in the RPMB buffer 1220 (“YES” at step S170), the RPMB buffer 1220 outputs the is searched second RPMB data to the host 2000 at step S190.

When the second RPMB is not stored in the RPMB buffer 1220 (“NO” at step S170), the processor 1230 controls the memory device 1100 to read a second RPMB data group including the second RPMB data among the plurality of RPMB data stored in the RPMB. The memory device 1100 performs a read operation on the RPMB under the control of the processor 1230, and the second RPMB data group read as a result of the read operation is stored in the RPMB buffer 1220. The first RPMB data group temporarily stored in the RPMB buffer 1220 may be removed.

After this, by returning to the step S190, the second RPMB data stored in the RPMB buffer 1220 is output to the host 2000 at step S190.

As described above, according to an embodiment of the present disclosure, when a read request for RPMB data is received from the host 2000, the memory controller 1200 reads a RPMB data group that has a data size larger than that of the RPMB data and includes the RPMB data, and stores the RPMB data group in the RPMB. After this, the memory controller 1200 outputs the RPMB data to the host 2000, and allows the other RPMB data to remain in the RPMB buffer 1220. After this, when a read request for new RPMB data is received from the host 2000, and the new RPMB data is stored in the RPMB buffer 1220, the memory controller 1200 outputs the new RPMB data stored in the RPMB buffer 1220 to the host 2000 without any read operation of the memory device 1100.

FIG. 11 is a diagram illustrating another embodiment of the memory system.

Referring to FIG. 11, the memory system 30000 may be implemented as a cellular phone, a smart phone, a tablet PC, a personal digital assistant (PDA), or a wireless communication device. The memory system 30000 may include a memory device 1100 and a memory controller 1200 capable of controlling an operation of the memory device 1100. The memory controller 1200 may control a data access operation of the memory device 1100, e.g., a program operation, an erase operation, a read operation, or the like under the control of a processor 3100.

Data programmed in the memory device 1100 may be output through a display 3200 under the control of the memory controller 1200.

The memory device 1100 and the memory controller 1200 may be configured and operated identically to the memory device 1100 and the memory controller 1200 of FIG. 1.

A radio transceiver 3300 may transmit/receive radio signals through an antenna ANT. For example, the radio transceiver 3300 may convert a radio signal received through the antenna ANT into a signal that can be processed by the processor 3100. Therefore, the processor 3100 may process a signal output from the radio transceiver 3300 and transmit the processed signal to the memory controller 1200 or the display 3200. The memory controller 1200 may transmit the signal processed by the processor 3100 to the semiconductor memory device 1100. Also, the radio transceiver 3300 may convert a signal output from the processor 3100 into a radio signal, and output the converted radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the memory controller 1200, data output from the radio transceiver 3300, or data output from the input device 3400 can be output through the display 3200.

In some embodiments, the memory controller 1200 capable of controlling an operation of the memory device 1100 may be implemented as a part of the processor 3100, or be implemented as a chip separate from the processor 3100.

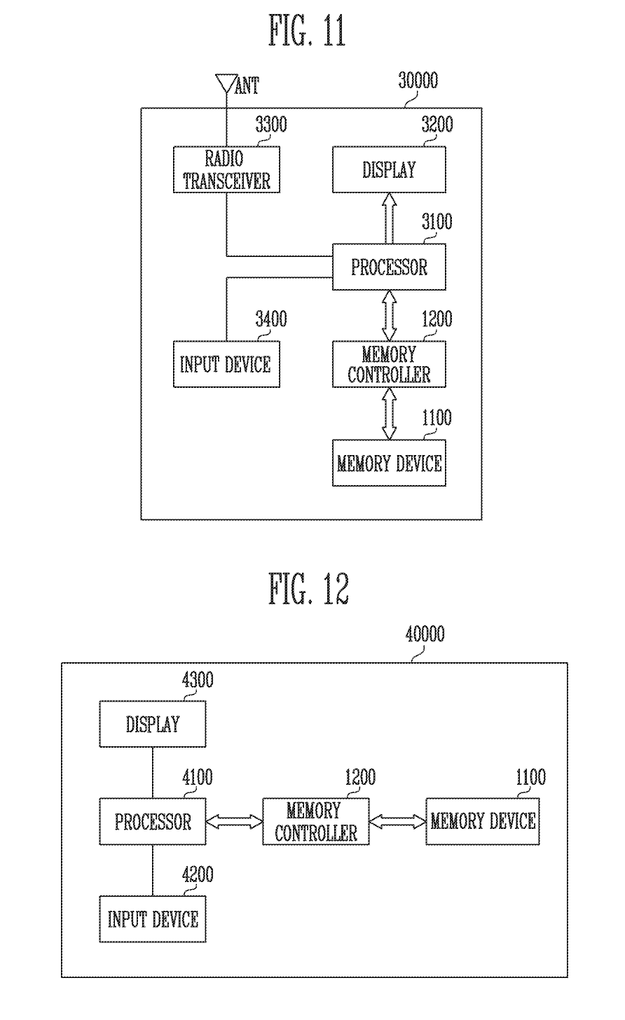

FIG. 12 is a diagram illustrating another embodiment of the memory system.

Referring to FIG. 12, the memory system 40000 may be implemented as a personal computer (PC), a tablet PC, a net-book, an e-reader, a personal digital assistant (PDA), a portable multimedia player (PMP), an MP3 player, or an MP4 player.

The memory system 40000 may include a memory device 1100 and a memory controller 1200 capable of controlling a data processing operation of the memory device 1100. The memory device 1100 and the memory controller 1200 may be configured and operated identically to the memory device 1100 and the memory controller 1200 of FIG. 1.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 1200. In some embodiments, the memory controller 1200 capable of controlling an operation of the memory device 1100 may be implemented as a part of the processor 4100, or be implemented as a chip separate from the processor 4100.

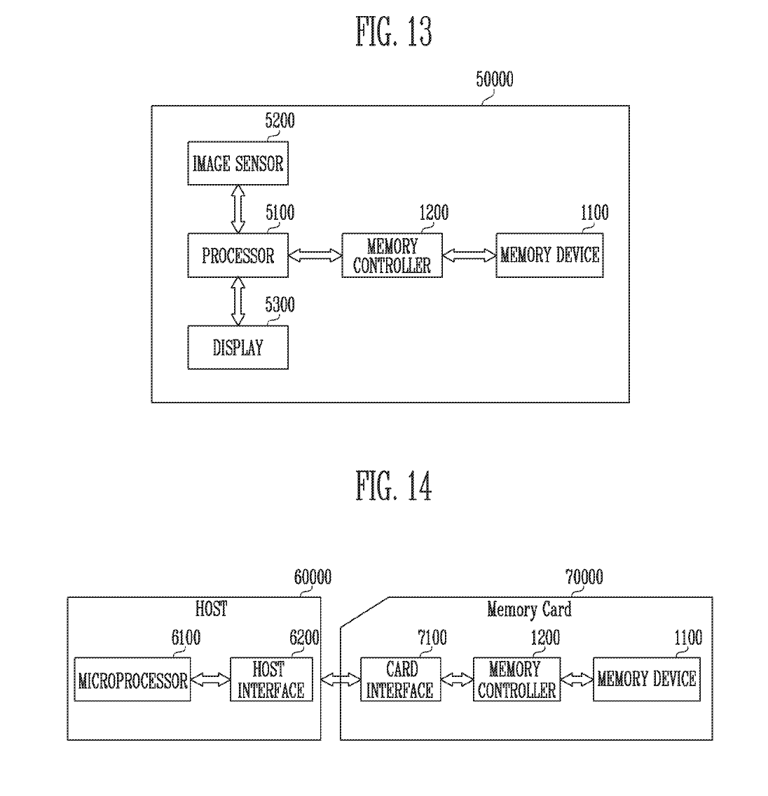

FIG. 13 is a diagram illustrating another embodiment of the memory system.

Referring to FIG. 13, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a memory controller 1200 capable of controlling a data processing operation of the memory device 1100, e.g., a program operation, an erase operation, or a read operation. The memory device 1100 and the memory controller 1200 may be configured and operated identically to the memory device 1100 and the memory controller 1200 of FIG. 1.

An image sensor 5200 of the memory system 50000 may convert an optical image into digital signals, and the converted digital signals may be transmitted to a processor 5100 or the memory controller 1200. Under the control of the processor 5100, the converted digital signals may be output through a display 5300, or be stored in the memory device 1100 through the memory controller 1200. In addition, data stored in the memory device 1100 may be output through the display 5300 under the control of the processor 5100 or the memory controller 1200.

In some embodiments, the memory controller 1200 capable of controlling an operation of the memory device 1100 may be implemented as a part of the processor 5100, or be implemented as a chip separate from the processor 5100.

FIG. 14 is a diagram illustrating another embodiment of the memory system.

Referring to FIG. 14, the memory system 70000 may be implemented as a memory card or a smart card. The memory system 70000 may include a memory device 1100, a memory controller 1200, and a card interface 7100. The memory device 1100 and the memory controller 1200 may be configured and operated identically to the memory device 1100 and the memory controller 1200 of FIG. 1.

The memory controller 1200 may control data exchange between the memory device 1100 and the card interface 7100. In some embodiments, the card interface 7100 may be a Secure Digital (SD) card interface or a Multi-Media Card (MMC) interface, but the present disclosure is not limited thereto.

The card interface 7100 may interface data exchange between a host 60000 and the memory controller 1200 according to a protocol of the host 60000. In some embodiments, the card interface 7100 may support a Universal Serial Bus (USB) protocol and an Inter-Chip (IC)-USB protocol. The card interface 7100 may mean hardware capable of supporting a protocol used by the host 60000, software embedded in the hardware, or a signal transmission scheme.

When the memory system 70000 is coupled to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 under the control of a microprocessor 6100.

According to aspects of the present disclosure, the performance of the memory system can be enhanced by improving the read operation of a replay protected memory block.

Various embodiments have been disclosed herein, and although specific terms are employed, they are used and are to be interpreted in a generic and descriptive sense and not for purpose of limitation. In some instances, as would be apparent to one skilled in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory system comprising:
a memory device including a replay protected memory block (RPMB) and a normal memory block; and
a memory controller configured to control overall operations of the memory device,
wherein the memory controller controls the memory device to read, from the RPMB, a first RPMB data group including first data stored in the RPMB in response to a read request for the first data, which is received from a host, temporarily store the first RPMB data group, and output the first data in the first RPMB data group to the host.

2. The memory system of claim 1, wherein the first data has a first data size, and the first RPMB data group has a second data size larger than the first data size.

3. The memory system of claim 2, wherein the RPMB includes an area accessed using an authentication key stored in the RPMB.

4. The memory system of claim 3, wherein, when a message authentication code (MAC) calculated using the authentication key is equal to an MAC included in the read request received from the host, the memory controller allows the access to the RPMB.

5. The memory system of claim 4, wherein the memory controller includes:
a RPMB engine configured to receive the read request from the host, and perform an authentication operation, using the MAC included in the read request and the MAC calculated using the authentication key;
a processor configured to control the memory device to perform a read operation on the first RPMB data group stored in the RPMB, when the read request is authenticated by the RPMB engine; and
a RPMB buffer configured to temporarily store the first RPMB data group read from the RPMB and then output the first data to the host.

6. The memory system of claim 5, wherein the second data size is equal to a data size of a page unit of the normal memory block or the maximum capacity of the RPMB buffer.

7. The memory system of claim 5, wherein, when a read request for second data stored in the RPMB is received from the host, the memory controller outputs the second data stored in the RPMB buffer to the host without any read operation on the RPMB when the second data is included in the first RPMB data group stored in the RPMB buffer.

8. The memory system of claim 7, wherein the RPMB buffer searches to determine whether the second data is included in the first RPMB data group, and outputs, as a search result, the second data to the host when the second data is included in the first RPMB data group.

9. The memory system of claim 7, wherein, when it is determined that the second data is not included in the first RPMB data group, the memory controller controls the memory device to read a second RPMB data group including the second data from the RPMB, temporarily store the second RPMB data group in the RPMB buffer, and output the second data in the second RPMB data group to the host.

10. A memory system comprising:
a memory device including a replay protected memory block (RPMB); and
a memory controller configured to control overall operations of the memory device,
wherein the memory controller controls the memory device to read, from the RPMB, a first RPMB data group including first data stored in the RPMB in response to a read request for the first data, which is received from a host, output the first data in the read first RPMB data group to the host, and temporarily store the other data in the first RPMB data group.

11. The memory system of claim 10, wherein the RPMB is an area accessed using an authentication key stored in the RPMB.

12. The memory system of claim 11, wherein, when an MAC calculated using the authentication key is equal to an MAC included in the read request received from the host, the memory controller allows the access to the RPMB.

13. The memory system of claim 12, wherein the memory controller includes:
a RPMB engine configured to receive the read request from the host, and perform an authentication operation, using the MAC included in the read request and the MAC calculated using the authentication key;
a processor configured to control the memory device to perform a read operation on the first RPMB data group stored in the RPMB, when the read request is authenticated by the RPMB engine; and
a RPMB buffer configured to temporarily store the first RPMB data group read from the RPMB and then output the first data to the host.

14. The memory system of claim13, wherein, when a read request for second data stored in the RPMB is received from the host, the memory controller outputs the second data stored in the RPMB buffer to the host without any read operation on the RPMB when the second data is included in the first RPMB data group stored in the RPMB buffer.

15. The memory system of claim 10, wherein a data size of the first RPMB data group is larger than that of the first data.

16. A method for operating a memory system including a RPMB, the method comprising:
receiving from a host a first read request for first data stored in the RPMB;
checking whether the first read request has been authenticated through an authentication operation;
when it is determined that the first read request has been authenticated, reading a first RPMB data group including the first data, and temporarily storing the read first RPMB data group by performing a read operation on the RPMB; and
outputting the first data in the read first RPMB data group to the host, and maintaining the other data except the first data in the first RPMB data group as temporarily stored.

17. The method of claim 16, wherein, when an MAC calculated by an authentication key stored in the RPMB is equal to an MAC included in the first read request, the authentication operation allows access to the RPMB.

18. The method of claim 16, wherein the first data has a first data size, and the first RPMB data group has a second data size larger than the first data size.

19. The method of claim 16, further comprising:
after an operation on the first read request is completed, receiving from the host a second read request for second data stored in the RPMB;
checking whether the second read request has been authenticated through the authentication operation, and searching to determine whether the second data is included in the other data that is temporarily stored; and
when it is determined that the second data is included in the other data, outputting the second data included in the other data to the host.

20. The method of claim 19, further comprising:
when it is determined that the second data is not included in the other data, reading a second RPMB data group including the second data and temporarily storing the read second RPMB data group by performing the read operation on the RPMB; and
outputting the second data in the read second RPMB data group to the host, and maintaining the other data except the second data in the second RPMB data group as temporarily stored.
